(19) United States
(12) Patent Application Publication
(10) Pub. No.: US 2004/0207041 A1
(43) Pub. Date: Oct. 21, 2004

(54) Capacitor arrangement and method for producing such a capacitor arrangement

(76) Inventor: Luc M.F. De Maaijer, Belfeld (NL)

Correspondence Address: SQUIRE, SANDERS & DEMPSEY L.L.P., 14TH FLOOR, 8000 TOWERS CRESCENT, TYSONS CORNER, VA, 22182, US

(21) Appl. No.: 10/483,806

(22) PCT Filed: Jul. 17, 2001
(86) PCT No.: PCT/EP01/08227

(51) Int. Cl. H01L 29/00

(52) U.S. Cl. 257/532

(57) ABSTRACT

The invention relates to a capacitor arrangement in a semiconductor layout, comprising capacitors formed on a substrate (1) by a first layer (2′, 2″) of a conductive material and a second layer (3′, 3″) of a conductive material with an insulating material (4) in between said first (2′, 2″) and said second (3′, 3″) layer of conducting material. In order to improve the design of such an arrangement, it is proposed that for each desired ideal capacitor (C1-C4), a pair of a first and a second capacitor (C1′-C4′, C1″-C4″) is provided. The first and second capacitor (C1′-C4′, C1″-C4″) of each pair are connected in a way offering a pair of terminals, at each of which terminals of a respective pair of terminals an essentially equal parasitic capacitance (Csub) formed between first layers (2′, 2″) of conductive material and said substrate (1) is achieved. The invention equally relates to a method for producing such an arrangement.

### FIELD OF THE INVENTION

The invention relates to a capacitor arrangement in a semiconductor layout, which arrangement comprises capacitors formed on a substrate by a first layer of a conductive material and a second layer of a conductive material with an insulating material in between said first and said second layer of conducting material. The invention further relates to a method for producing such a capacitor arrangement. Finally, the invention relates to a poly phase filter, an electronic circuit, and a terminal and a network element of a communications system which comprise such a capacitor arrangement.

### BACKGROUND OF THE INVENTION

Capacitor arrangements in a semiconductor layout can be employed for various electronic circuits, for example in circuits comprising a poly phase filter. In the design of capacitor arrangements, problems may arise that will be described exemplarily for a poly phase filter.

A poly phase filter is able to filter out positive or negative frequencies. Due to its ability to suppress only negative or only positive frequencies, poly phase filters are frequently used in mobile phones or in other units of a communications system.

For illustration, FIG. 1 shows an ideal circuit of a poly phase filter.

The filter comprises a separate input/output terminal for signal phases of 0°, 45°, 90°, 135°, 180°, 225°, 270, and 315°. Between the terminals for 0° and 315°, the terminals for 90° and 45°, the terminals for 180° and 135°, and the terminals for 270° and 225° respectively, a resistance R1-R4 is arranged. The four resistances R1-R4 have equal dimensions. In addition, an ideal capacitor C1-C4 is arranged between the terminals for 0° and 45°, the terminals for 90° and 135°, the terminals for 180° and 225°, and the terminals for 270° and 315° respectively. Also the ideal capacitors C1-C4 have equal dimensions.

By grounding the 90° and the 270° terminal of the poly phase filter, the filter can also be used as a very accurate phase shifter.

The depicted circuit is an ideal symmetric bridge circuit without parasitic capacitances.

However, in order to achieve a small sized active poly phase filter, it is desirable that the filter is realized as an on-chip filter. In chip technologies, most capacitors are formed on a semiconductive substrate and are composed of two layers of conductive material which are separated by an insulating material. With capacitors formed on a semiconductive substrate, the layer most close to the substrate has an additional capacitance to the substrate. Thus, the resulting capacitance is asymmetrical, since a parasitic capacitance is only present at the terminal connected to the lower layer of the capacitor.

FIG. 2 shows on the left hand side the symbol for such an unbalanced capacitor C comprising a parasitic capacitance, the location of the parasitic capacitance being indicated by a plate that is bent. On the right hand side of FIG. 2, an equivalent circuit of a capacitor with a parasitic capacitance is shown. In this circuit, one terminal of the capacitor C is connected to the substrate by a parasitic capacitance C_{parasitic}.

The design of poly phase filters making use of such on-chip capacitors is rather difficult, since they are extremely sensitive to parasitic influences. Poly phase filters employed in communications systems, for instance, usually use frequencies around 5 GHz, and with such frequencies, the parasitic capacitances have a significant influence on the operation of the filter. The parasitic capacitances can cause corner frequency shifts and changes in the input impedance of the filter. Capacitors C1 to C4 and resistances R1 to R4 have to be accurately matched in value and parasitic capacitances have to be added in a well balanced way to each branch. However, parasitic influences, especially the mentioned parasitic capacitance, are unavoidable and change the characteristics of the poly phase filter.

### SUMMARY OF THE INVENTION

It is an object of the invention to provide a capacitor arrangement of a semiconductor layout with an improved design.

This object is reached on the one hand with a capacitor arrangement in a semiconductor layout comprising capacitors formed on a substrate by a first layer of a conductive material and a second layer of a conductive material with an insulating material in between said first and the second layer of conducting material, wherein for each ideal capacitor desired in the capacitor arrangement a pair of a first and a second capacitor is provided. The respective first and second capacitors are connected in a way offering a pair of terminals. The connection is further realized such that at each of the terminals of a respective pair of terminals an essentially equal parasitic capacitance formed between first layers of conductive material and the substrate is achieved.

On the other hand, the object is reached with a corresponding method for producing a capacitor arrangement in a semiconductor layout. The method comprises forming for each ideal capacitor desired in the capacitor arrangement a pair of capacitors on a substrate, which capacitors include a first layer of a conductive material, a second layer of a conductive material, and an insulating material in between said first and said second layer of conducting material. The method further comprises connecting the capacitors of each pair of capacitors in a way that they offer a pair of terminals and that at each of these terminals of a respective pair of terminals an essentially equal parasitic capacitance formed between first layers of conductive material and the substrate is achieved.

Further proposed are a poly phase filter, an electronic circuit, a terminal for a communications system, for instance a mobile terminal, and a network element for a communications system comprising the proposed capacitor arrangement.

The parasitic capacitance formed between the first layer of a semiconductor capacitor and the substrate are visible only at one of the terminals of this capacitor, i.e. at the terminal connected to the first layer of the capacitor. The invention proceeds from the idea that if each desired ideal capacitor is formed by two real capacitors, each forming an additional parasitic capacitance between the respective first layer and the substrate, the two capacitors can be connected in a way that a similar parasitic capacitance can be provided at each terminal. That is, the parasitic capacitance resulting from the first real semiconductor capacitor is mainly visible at the first terminal and the parasitic capacitance resulting from the second real semiconductor capacitor is mainly visible at the second terminal. Desired ideal capacitor means any capacitor of a capacitor arrangement that would optimize the operation of the capacitor arrangement or of a circuit in which the capacitor arrangement is integrated if it could be realized as ideal capacitor.

It is thus an advantage of the invention that it enables a symmetric capacitor arrangement in a semiconductor layout by balancing the undesired parasitic capacitances formed by each capacitor.

Preferred embodiments of the invention become apparent from the subclaims.

The capacitors of each pair of capacitors are preferably connected in a way that each pair of terminals carries signals which are rotation symmetrically arranged to ground.

A first possibility of connecting the capacitors of the employed pairs of capacitors in a way that pairs of terminals are obtained at which terminals of a respective pair of terminals essentially equal parasitic capacitances are seen is given by an anti series connection of the two capacitors or by an anti parallel connection of the two capacitors.

If the capacitors of each pair are connected in anti series, however, the capacity of the capacitors has to be increased. Therefore the capacitors of the provided pairs of capacitors are preferably connected in anti parallel. This results in a smaller required chip area and consequently in lower costs for the semiconductor layout.

With the proposed employment of additional capacitors, additional connections become necessary, and sometimes it will not be possible to avoid that wires connecting the capacitors of the different pairs and/or wires connecting a respective pair with the terminals cross each other. Each crossing, however, results in an additional parasitic capacitance. If no special care is taken, this would make the arrangement non-symmetric again and would cause a loss in performance. Therefore, the connections are advantageously designed in a way that the parasitic capacitance is the same for each of the connections between the capacitors of the different pairs. To this end, it should be taken care that for each connection the total size of the area of crossings is equal. Preferably, the routing is moreover carried out in a way that the length of all connections is identical.

In integrated circuit (IC) processes, the insulator applied for a variety of capacitors at the same time often changes in thickness over with the distance. Therefore, the first and the second capacitor of each pair of capacitors are preferably arranged diagonally to each other in the corners of a rectangular area of the semiconductor layout. If the capacitors of another pair is then arranged in the remaining two corners of the rectangular area, the resulting capacity of each pair of capacitors is matched, since a change in thickness will influence both capacities in an equal amount.

In order to be able to provide a rotation symmetry in a capacitor arrangement with diagonally arranged capacitors, attention should further be paid to the selection of the pairs of capacitors which are combined in each rectangular area. Those capacitors required to be equal should be arranged together in a rectangular area.

In a preferred embodiment of the invention, the capacitor arrangement is used for a poly phase filter as the one described above with reference to FIG. 1. In this filter, preferably pairs of capacitors placed between the terminals for 0° and 45° and the terminals for 180° and 225° are arranged diagonally in a first essentially rectangular area of said semiconductor layout. If these capacitors load the respective branches of the arrangement equally, a problem does not occur, since the filter remains symmetric. Correspondingly, pairs of capacitors placed between the terminals for 90° and 135° and the terminals for 270° and 315° are arranged diagonally in a second essentially rectangular area of said semiconductor layout.

The invention can be employed in particular, though not exclusively, for poly phase filters. Such poly phase filters can be integrated for example in mobile phones or other units of communications systems.

### BRIEF DESCRIPTION OF THE FIGURES

In the following, the invention will be explained in more detail with reference to drawings, of which

FIG. 1 shows an ideal circuit of a poly phase filter;

FIG. 2 shows the symbol and the equivalent circuit of a real capacitor of an IC;

FIG. 3 shows a circuit of an embodiment of a poly phase filter designed according to the invention;

FIG. 4 schematically illustrates a side view of a semiconductor layout with a pair of capacitors employed in the circuit of FIG. 3;

FIG. 5 schematically shows a top view on a part of a semiconductor layout employed for the circuit of FIG. 3;

FIG. 6 shows equivalent circuit for four capacitors connected according to the layout of FIG. 5; and

FIG. 7 shows a simplified equivalent circuit of a poly phase filter according to FIG. 3.

### DETAILED DESCRIPTION OF THE INVENTION

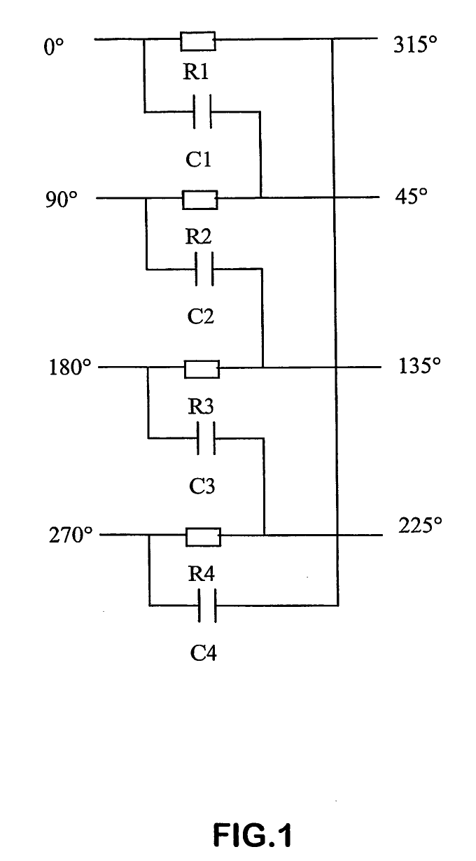

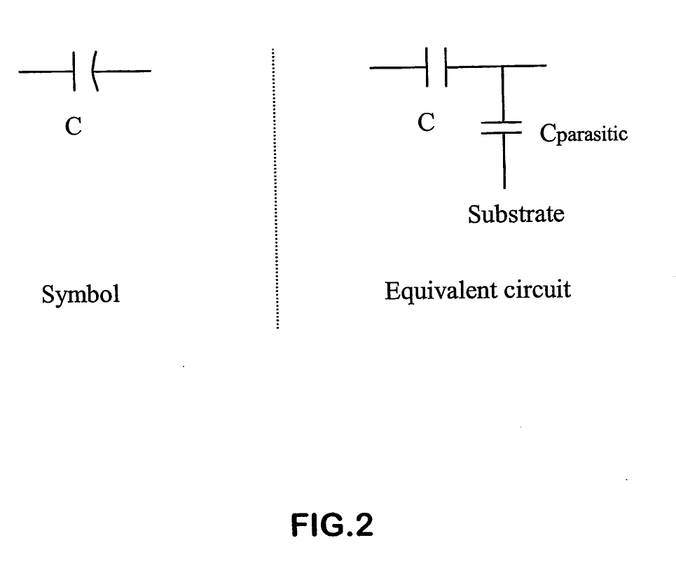

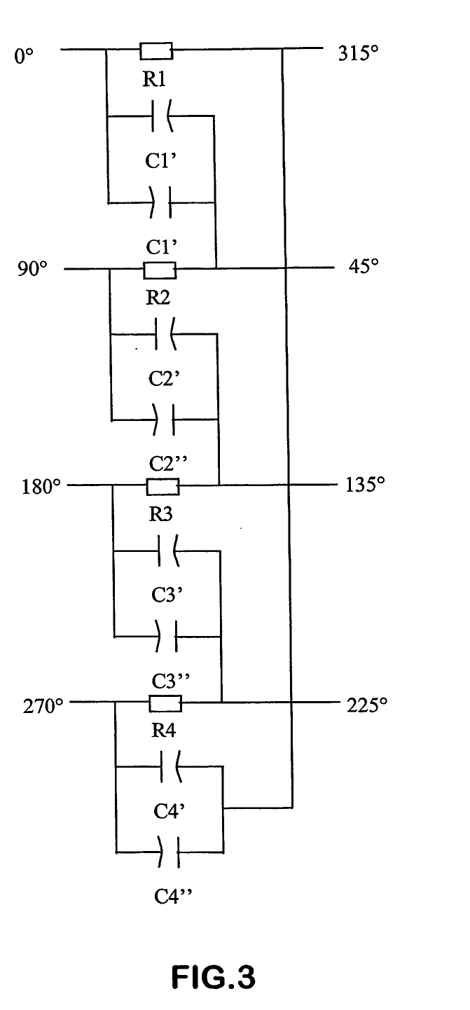

FIGS. 1 and 2 have already been described above. FIGS. 3 to 7 are introduced for illustrating an embodiment of the invention. Corresponding elements are referred to in all figures by the same reference signs.

In the embodiment of the invention, each of the poly phase capacitors C1 to C4 in the poly phase filter circuit of FIG. 1 is realized by a pair of two on-chip capacitors. This is illustrated in FIG. 3.

FIG. 3 shows a circuit of a poly phase filter, which circuit corresponds to the ideal circuit of FIG. 1, except that for each ideal capacitor C1 to C4 a pair of real capacitors C1′, C1″to C4′, C4″ is employed. Each real capacitors forms an additional parasitic capacitance as described with reference to FIG. 2. The capacitors C1′, C1″ to C4′, C4″ employed for each poly phase capacitor C1 to C4 are connected in anti parallel. This is indicated in the figure by locating the bent plate representing the parasitic capacitance of each real capacitor C1′, C1″ to C4′, C4″ once on the left hand side and once on the right hand side for each pair.

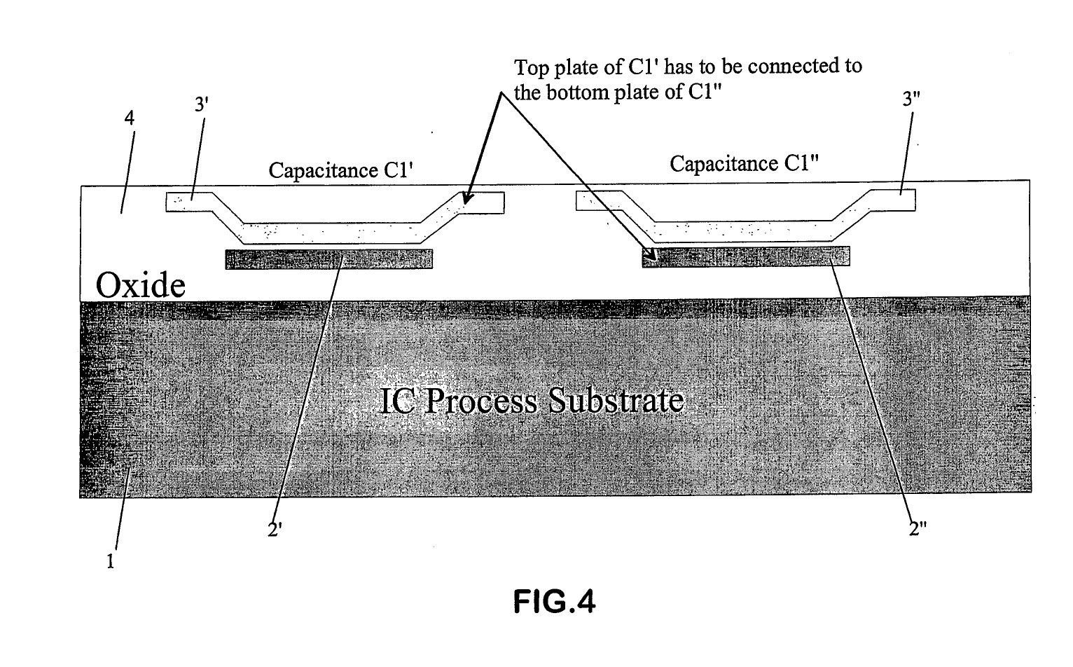

The structure of on-chip capacitors employed for obtaining the anti parallel pairs of capacitors of FIG. 3 is shown in FIG. 4, which is a schematic side view on an excerpt of a semiconductor chip with two capacitors. On top of an IC process substrate 1 of the semiconductor chip, e.g. a silicon oxide or silicon nitride substrate, an oxide layer 4 is formed. In this oxide layer 4, a first capacitor C1′ and a second capacitor C1″ are arranged. Each capacitor C1′, C1″ comprises a bottom plate 2′, 2″ formed by a first layer of conductive material close and in parallel to the substrate 1. Moreover, each capacitor C1′, C1″ comprises a top plate 3′, 3″ formed by a second layer of conductive material arranged essentially in parallel above the bottom plate 2′, 2″. Top and bottom plate of both capacitors C1′, C1″ are separated from each other by an insulating material. The insulating material is formed in this example equally by the oxide 4 in which the capacitors C1′, C1″ are embedded. The bottom plate 2′, 2″ of each of the capacitors C1′, C1″ forms in addition together with the substrate 1 a parasitic capacitance.

The two depicted capacitors C1′, C1″ are connected in anti parallel for forming the capacitor C1 of FIG. 1. To this end, the top plate 3′ of the first capacitor C1′ is connected to the bottom plate 2″ of the second capacitor C1″ and vice versa. The connections themselves are not depicted in the figure. Corresponding assemblies are provided for the other pairs of capacitors C2′,C2″-C4′,C4″ of FIG. 3 employed for the ideal capacitors C2-C4 of FIG. 1.

The advantage of the circuit of FIG. 3 is that a parasitic capacitance to the substrate is available at each of the terminals, not only at half of the terminals, which makes the filter electrically symmetric.

It has to be taken care, however, that no other asymmetries are introduced by employing for each poly phase capacitor two capacitors connected in anti parallel.

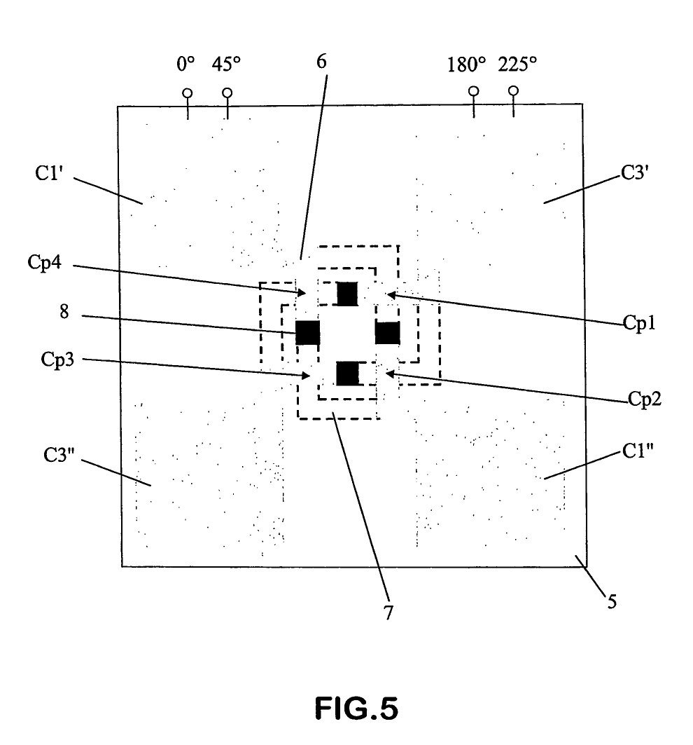

An embodiment of a semiconductor layout according to the invention with which additional asymmetries can be avoided is depicted in FIG. 5. FIG. 5 is a top view on a rectangular area 5 of a semiconductor layout in which the capacitors C1′, C1″, C3′, C3″ of two of the pairs of capacitors of the poly phase filter of FIG. 3 are arranged. The upper layers of the capacitors C1′, C1″, C3′, C3″ are depicted in the figure as gray rectangles. The capacitors C1′, C1″ and C3′, C3″ of each pair are positioned in corners of the rectangular area 5 which are diagonal to each other. The capacitors of a pair are placed in diagonal to ensure that a change in thickness will influence both pairs in an equal amount. Thus, the matching between the two poly phase capacitors C1, C3 formed by the two pairs is improved. The capacitors C1′, C1″ and C3′, C3″ of each pair are further connected in anti parallel as described with reference to FIG. 4. One capacitor C1′, C3′ of each pair is provided in addition with connections to two of the terminals 0°, 45° and 180°, 225° in FIG. 3.

In the arrangement of FIG. 5, it is unavoidable that some of the connecting wires are crossing each other. Each crossing results in an additional parasitic capacitance. If such parasitic capacitances make the poly phase filter non-symmetric again, this would cause a loss in performance. Therefore, further special care has to be taken in the routing of the connections between the capacitors C1′, C1″ and C3′, C3″. An advantageous embodiment of the routing is depicted in the center of the rectangular area 5 of FIG. 5.

The connections of the capacitors C1′, C1″ and C3′, C3″ of each pair are formed more specifically with the aid of an upper wire 6 connected to the upper layer of each capacitor and on the other hand by a lower wire 7 connected to the lower layer of each capacitor. The upper wires 6 are equally depicted in the figure in gray, while the lower wires 7 are depicted with dashed lines. The upper wire of a first capacitor C1′ of a first poly phase capacitor C1 is connected to the lower wire of the second capacitor C1″ of the first poly phase capacitor C1. Equally, a lower wire of the first capacitor C1′ of the first poly phase capacitor C1 is connected to the upper wire of the second capacitor C1″ of the first poly phase capacitor C1. The two capacitors C3′, C3″ of the other poly phase capacitor C3 are connected in the same way by upper and lower wires. All connections of upper and lower wires are indicated in FIG. 5 as black rectangles 8.

It can be seen in the figure that the layout of the connections is symmetric, and that the areas of crossing wires 6, 7 are equal for each connection. Thus, the layout provides equal parasitic capacitances Cp1-Cp4 for each connection.

When combining any two of the pairs of capacitors of FIG. 3 in a rectangular area 5 as depicted in FIG. 5, equal parasitic capacitances may be achieved for the respective connections, but a rotation symmetry for the whole circuit of FIG. 3 might not be achieved. Rotation symmetry can only be achieved by combining the right pairs of capacitors forming poly phase capacitors C1-C4 in a rectangular area of a semiconductor layout. When selecting the pairs of capacitors that are to be combined, it is to be noted that no problems arise by parasitic capacitances as long as they are equal between phases shifted by 180°, i.e. between the terminals for 0° and 180°, the terminals for 90° and 270°, the terminals for 45° and 225° and the terminals for 135° and 315°. Such parasitic capacitances basically do not interfere with the operation of the desired poly phase capacitors C1-C4.

Thus, rotation symmetry can be achieved by combining the capacitors C1′, C1″, C3′, C3″ for the first and the third poly phase capacitor C1, C3 and by combining the capacitors C2′, C2″, C4′, C4″ for the second and the fourth poly phase capacitor C2, C4, since this combination enables to provide the required equal values for the parasitic capacitances. Accordingly, poly phase capacitors C1 and C3 were selected for combination in the arrangement of FIG. 5. The same arrangement will be employed for a combination of poly phase capacitors C2 and C4 in some other rectangular area of the semiconductor layout.

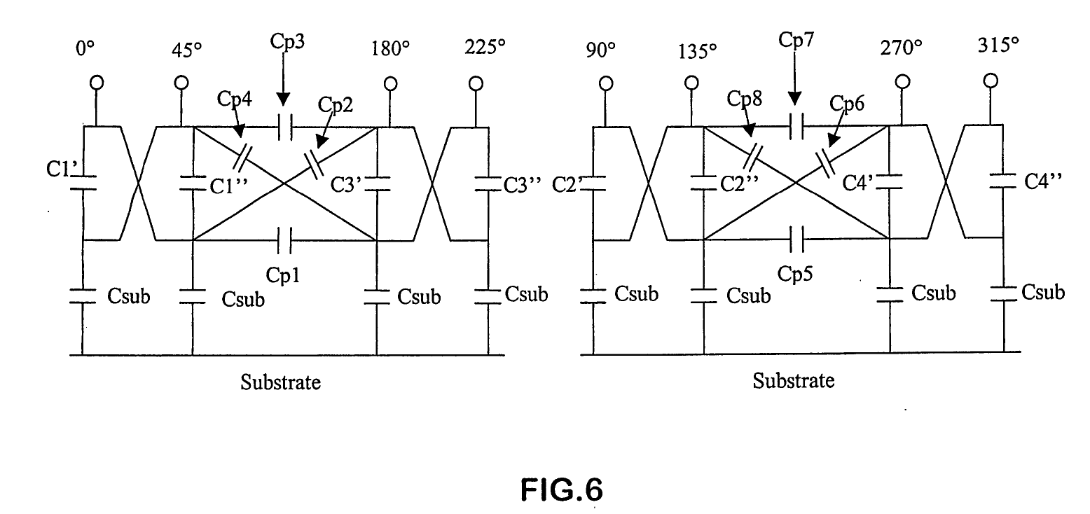

FIG. 6 shows the resulting equivalent circuit for the four poly phase capacitors C1 to C4, each formed by two connected capacitors C1′, C1″ to C4′, C4″. The circuit on the left hand side is the equivalent of the structure of FIG. 5. Respectively two of the capacitors C1′, C1″ and C3′, C3″ are connected in anti parallel. As can be seen, the lower layer of each capacitor C1′, C1″, C3′, C3″ forms a parasitic capacitance with the substrate. In addition parasitic capacitances Cp1 to Cp4 are formed in this order between the upper layer of capacitor C1′ and the lower layer of C3′, between the upper layer of capacitor C1′ and the upper layer of C3′, between the lower layer of capacitor C1′ and the upper layer of capacitor C3′, and between the lower layer of capacitor C1′ and the lower layer of capacitor C3′. The upper layer of capacitor C1′ is connected to terminal 0° and its lower layer to terminal 45°. The upper layer of capacitor C3′ is connected to terminal 180° and its lower layer to terminal 225°.

The circuit depicted on the right hand side of FIG. 6 is the equivalent of a structure corresponding to the structure of FIG. 5 in which instead of poly phase capacitors C1 and C3, poly phase capacitors C2 and C4 were combined. The circuit therefore corresponds exactly to the circuit depicted on the left hand side, except that here, the capacitors C1′, C1″ of poly phase capacitor C1 were substituted by capacitors C2′, C2″ of poly phase capacitor C2, and that capacitors C3′, C3″ of poly phase capacitor C3 were substituted by capacitors C4′, C4″ of poly phase capacitor C4. Accordingly, the upper layer of capacitor C2′ is connected to terminal 90° and its lower layer to terminal 135°. The upper layer of capacitor C4′ is connected to terminal 270° and its lower layer to terminal 315°. The parasitic capacitors corresponding to parasitic capacitances Cp1 to Cp4 of the circuit for poly phase capacitors C1 and C3 are referred to by Cp5 to Cp8.

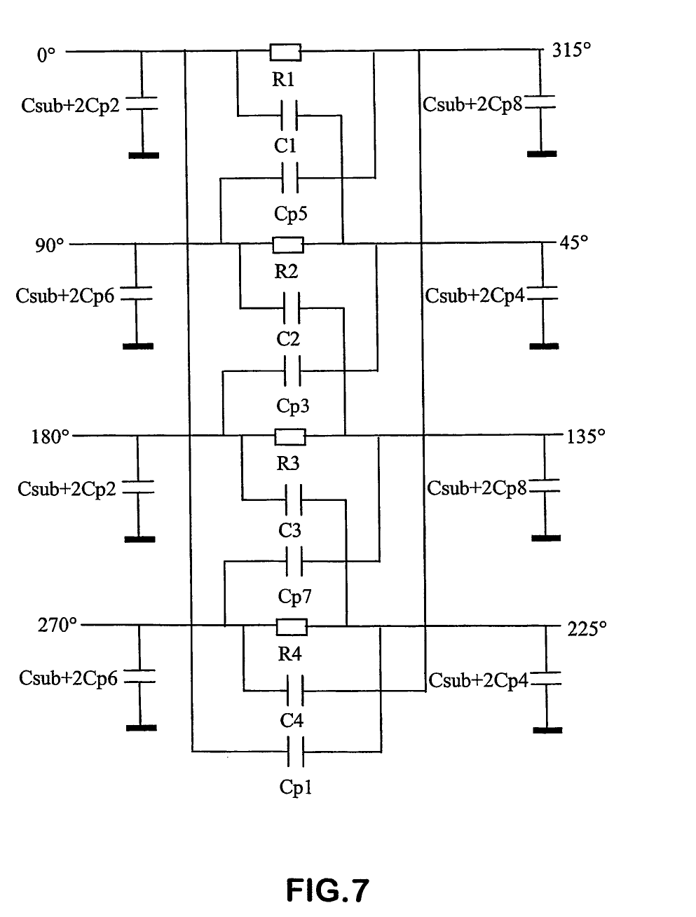

FIG. 7 finally shows a simplified equivalent circuit of an entire poly phase filter according to the invention. The simplification is based on the knowledge that parasitic capacitors between the terminals 0° and 180°, 90° and 270°, 45° and 225°, 135° and 315° are not a problem if they are equal. The circuit of FIG. 7 corresponds to the circuit of FIG. 3. The depicted poly phase capacitors C1 to C4 are all formed by a pair of capacitors and can be assumed to be ideal as in FIG. 1, since the resulting parasitic capacitances are included separately.

More specifically and in accordance with the circuits of FIG. 6, a parasitic capacitance Csub+2Cp2 is arranged between the 0° terminal and ground and equally between the 180° terminal and ground. A parasitic capacitance Csub+2Cp6 is arranged between the 90° terminal and ground and between the 270° terminal and ground. A parasitic capacitance of Csub+2Cp8 is arranged between the 315° terminal and ground and between the 135° terminal and ground. Further, a parasitic capacitance Csub+2Cp4 is arranged between the 45° terminal and ground and between the 225° terminal and ground. The parasitic capacitances mentioned are composed of capacitances Csub formed between the lower layers of the employed capacitors and the substrate, and of capacitances formed by wires crossing each other.

In addition, a parasitic capacitance Cp5 is arranged between the 315° terminal and the 90° terminal, a parasitic capacitance Cp3 between the 45° terminal and the 180° terminal, a parasitic capacitance Cp7 between the 135° terminal and the 270° terminal, and a parasitic capacitance Cp1 between the 225° terminal and the 0° terminal. These parasitic capacitances Cp1, Cp3, Cp5 and Cp7 also do not cause any problems if they are equal. If this condition is met, they could therefore also be referred to commonly by Cp.

Obviously, the poly phase filter depicted in FIG. 7 is thus rotation symmetric although parasitic capacitances have been added to the scheme.

In the presented embodiment of the invention, it is thus ensured that the input and output branches of a poly phase filter are equally loaded. By an advantageous arrangement of the capacitors of each pair of capacitors and by an advantageous routing of the wires connecting the capacitors of each pair, it is furthermore guaranteed that the circuit remains rotation symmetric.

The transfer function of an output of the poly phase filter shows that the parasitic effect causes the pole and the zero of the function to shift in opposite direction. The transfer function is given by:

$${U}_{θ} = \frac{( {U}_{θ + 45 °} + j * ω * R * {C}_{p} * {U}_{θ + 135 °} + j * ω * R * C * {U}_{θ + 315 °} )}{( 1 + j * ω * R * {C}_{p} + j * ω * R * C )}$$

In this equation, θ can be equal to 45°, 135°, 225° or 315°. For an example of θ=135°, and assuming the input voltages for the poly phase filter to be 1 for 0°, j for 90°, −1 for 180° and −j for 270°, the above equation can be simplified for the output U₃₁₅ at terminal 135° to:

$${U}_{315} = \frac{( 1 + j * ω * R * {C}_{p} + j + j * ω * R * C * - j )}{( 1 + j * ω * R * {C}_{p} + j * ω * R * C )} = \frac{( 1 + ω * R * ( C - {C}_{p} ) )}{( 1 + j * ω * R * ( {C}_{p} + C ) )}$$

It becomes apparent that the parasitic capacitance causes a shift in the pole and the zero. This change occurs in all four outputs and therefore the relative phase difference remains exactly 90°. Thus the phase shifter clearly benefits from this new layout.

In the case of a polyphase filter that is needed to select either positive or negative frequencies, the parasitic capacitances are causing a slight change in the frequency that is selected. That means, the parasitic capacitances cause a small amount of the not wanted band to pass through the filter. This portion however is less compared to the situation where a parasitic capacitance is only present in one branch or is active between only two nodes in the filter. Therefore the performance of the poly phase filter is improved by the new layout, when assuming that the parasitic capacitance is only a fraction of the wanted capacitance.

1-18. (Canceled)

19. Capacitor arrangement in a semiconductor layout, comprising capacitors formed on a substrate by a first layer of a conductive material and a second layer of a conductive material with an insulating material in between said first and said second layer of conducting material, and wherein for each ideal capacitor desired in said capacitor arrangement a pair of a first and a second capacitor is provided, which first and second capacitor of each pair of capacitors are connected in a way offering a pair of terminals, wherein said respective first and second capacitor are connected in anti parallel or in anti series so that at each of said terminals of a respective pair of terminals an essentially equal parasitic capacitance formed between first layers of conductive material and said substrate is achieved, and wherein each connection between first and second capacitors of the provided pairs of capacitors crosses other connections between first and second capacitors with the same total area of crossing so that a symmetric distribution of parasitic capacitances resulting at the crossing points of connections of different pairs of capacitors to the capacitors of said pairs of capacitors is ensured.

20. Capacitor arrangement according to claim 19, wherein the first and the second capacitor of each pair of capacitors are arranged diagonally to each other in the corners of an essentially rectangular area of said semiconductor layout, and wherein the first and the second capacitor of a respective other pair of capacitors are arranged in the remaining two corners of said essentially rectangular area.

21. Capacitor arrangement according to claim 20, wherein each of said pairs of capacitors is to be arranged in a different branch of an electronic circuit, wherein respective two pairs of capacitors have to load the branches in which they are arranged equally in order to provide a symmetric circuit, and wherein respective two pairs of capacitors which have to load the branches in which they are arranged equally in order to provide a symmetric circuit are arranged in an essentially rectangular area of said semiconductor layout.

22. Capacitor arrangement according to claim 20, wherein equal capacitors of said pairs of capacitors are arranged together in a respective essentially rectangular area such that each offered pair of terminals carries signals which are rotation symmetrically arranged to ground.

23. Capacitor arrangement according to claim 19 forming a part of a poly phase filter.

24. Use of a capacitor arrangement according to claim 23 for providing terminals for phases of 0°, 45°, 90°, 135°, 180°, 225°, 270°, and 315° of a poly phase filter, wherein a resistance is arranged between the terminals for 0° and 315°, between the terminals for 90° and 45°, between the terminals for 180° and 135°, and between the terminals for 270° and 225°, and wherein a pair of a respective first and second capacitor is arranged between the terminals for 0° and 45°, between the terminals for 90° and 135°, between the terminals for 180° and 225°, and between the terminals for 270° and 315°.

25. Use of a capacitor arrangement according to claim 24, wherein said pairs of capacitors between said terminals for 0° and 45° and said terminals for 180° and 225° are placed in a first essentially rectangular area of said semiconductor layout, and wherein said pairs of capacitors between said terminals for 90° and 135° and said terminals for 270° and 315° are placed in a second essentially rectangular area of said semiconductor layout, the first and the second capacitor of each pair of capacitors being positioned diagonally to each other in the corners of the respective rectangular area in which they are placed.

26. Poly phase filter comprising a capacitor arrangement according to claim 19.

27. Electronic circuit comprising a capacitor arrangement according to claim 19.

28. Mobile terminal for a communications system comprising a capacitor arrangement according to claim 19.

29. Network element for a communications system comprising a capacitor arrangement according to claim 19.

30. Method for producing a capacitor arrangement in a semiconductor layout, comprising
forming for each ideal capacitor desired in said capacitor arrangement a pair of a first and a second capacitor on a substrate, which capacitors include a first layer of a conductive material, a second layer of a conductive material, and an insulating material in between said first and said second layer of conducting material;
connecting the capacitors of each pair of capacitors in a way resulting in a pair of terminals, wherein the respective first and second capacitor of each provided pair of capacitors are connected in anti parallel or in anti series such that at each of said terminals of a respective pair of terminals an essentially equal parasitic capacitance formed between said first layers of conductive material and said substrate is achieved, and wherein each connection between said first and said second capacitors of said provided pairs of capacitors are routed such that they cross other connections between first and second capacitors with the same total area of crossing such that a symmetric distribution of parasitic capacitances resulting at the crossing points of connections of different pairs of capacitors to the capacitors of said pairs of capacitors is ensured.

31. Method according to claim 30, wherein said first and said second capacitor of each provided pair of capacitors are arranged diagonally to each other in the corners of an essentially rectangular area of said semiconductor layout, and wherein the first and the second capacitor of a respective other pair of capacitors are arranged in the remaining two corners of said essentially rectangular area.

32. Method according to claim 30 wherein each of said pairs of capacitors is to be arranged in a different branch of an electronic circuit, wherein respective two pairs of capacitors have to load the branches in which they are arranged equally in order to provide a symmetric circuit, and wherein said respective two pairs of capacitors which have to load the branches in which they are arranged equally in order to provide a symmetric circuit are arranged in an essentially rectangular area of said semiconductor layout.

33. Method according to claim 30 wherein equal capacitors of said pairs of capacitors are arranged together in a respective essentially rectangular area such that each pair of terminals carries signals which are rotation symmetrically arranged to ground.

34. Method according to claim 30, further comprising integrating said pairs of capacitors in an electronic circuit for a poly phase filter.

35. Method according to claim 34, comprising
providing terminals for phases of 0°, 45°, 90°, 135°, 180°, 225°, 270°, and 315°;
providing a resistance between said terminals for 0° and 315°, between said terminals for 90° and 45°, between said terminals for 180° and 135°, and between said terminals for 270° and 225°; and
arranging respectively one of the provided pairs of capacitors between said terminals for 0° and 45°, between said terminals for 90° and 135°, between said terminals for 180° and 225°, and between said terminals for 270° and 315°.

36. Method according to claim 35, wherein said pairs of capacitors between said terminals for 0° and 45° and said terminals for 180° and 225° are placed in a first essentially rectangular area of said semiconductor layout, and wherein said pairs of capacitors between said terminals for 90° and 135° and said terminals for 270° and 315° are placed in a second essentially rectangular area of said semiconductor layout, said first and said second capacitor of each pair of capacitors being positioned diagonally to each other in the corners of the respective rectangular area in which they are placed.
